(19) United States
(12) Patent Application Publication
(10) Pub. No.: US 2012/0104361 A1
(43) Pub. Date: May 3, 2012

(54) TRANSISTOR USING SOURCE ELECTRODE AND DRAIN ELECTRODE HAVING POINTED PORTIONS

(75) Inventor: CHIA-LING HSU, Tu-Cheng (TW)

(73) Assignee: HON HAI PRECISION INDUSTRY CO., LTD., Tu-Cheng (TW)

(21) Appl. No.: 12/970,962

(22) Filed: Dec. 17, 2010

(30) Foreign Application Priority Data
Oct. 28, 2010 (TW) 99136866

(51) Int. Cl. H01L 29/786; B82Y 99/00

(52) U.S. Cl. 257/24; 257/E29.273; 977/762; 977/938

(57) ABSTRACT

A transistor includes a substrate, a source electrode, a drain electrode and a nanowire-layer. The source electrode, the drain electrode and the nanowires-layer are formed on the substrate. The source electrode includes a plurality of first pointed portions, and the drain electrode includes a plurality of second pointed portions each aligned with a corresponding first pointed portions. The nanowire-layer is interconnected between the first pointed portions and the second pointed portions.

### BACKGROUND

1. Technical Field

The present disclosure relates to a transistor, and more particularly, a transistor using source electrode and drain electrode having pointed portions.

2. Description of Related Art

Nanowires have been widely used in transistors because of their excellent mechanical characteristics, quantum effects, and high surface to volume ratios. The nanowires should be oriented along a certain direction in order to function as an effective semiconductor layer. However, in a traditional fabrication process of the transistor, it is difficult to orient the nanowires substantially in a desired direction. Therefore, it is needed to provide a transistor which can overcome the above shortcomings.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a transistor in accordance with an exemplary embodiment.

FIG. 2 is a cross-sectional view of the transistor of FIG. 1, taken along line II-II.

FIG. 3 shows successive stages of a process of fabricating the transistor of FIG. 1.

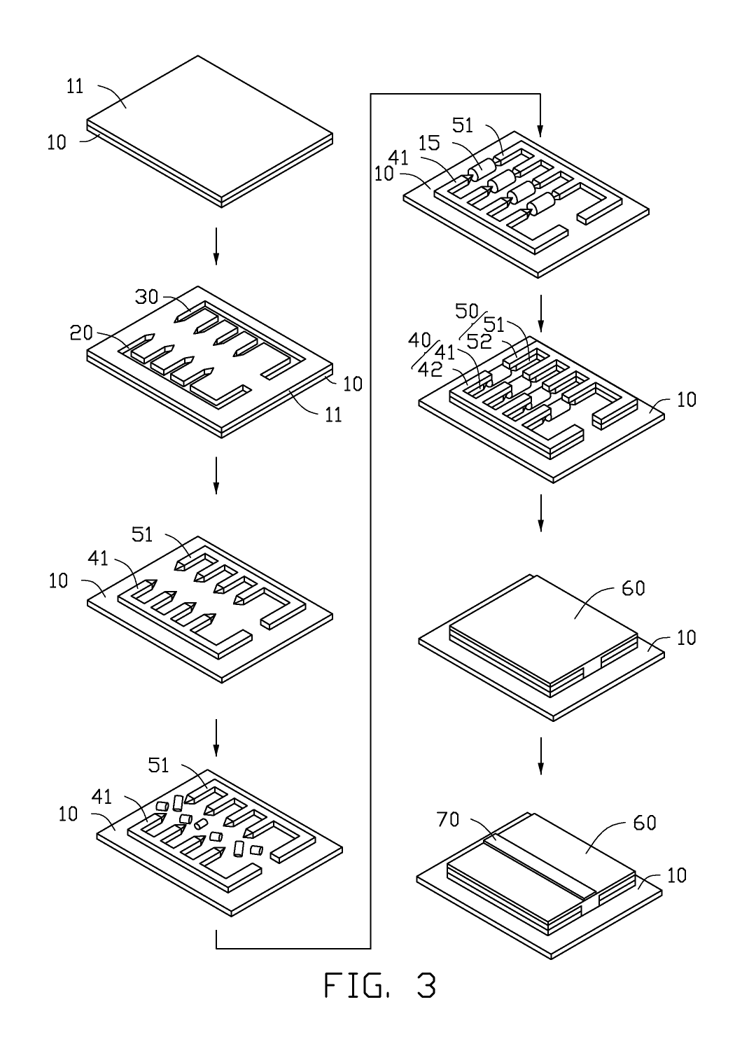

### DETAILED DESCRIPTION

Embodiments of the present transistor will now be described in detail below and with reference to the drawings.

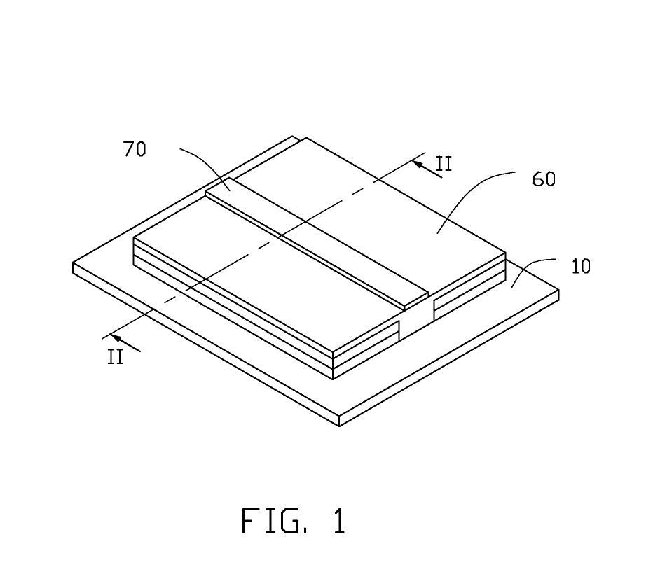

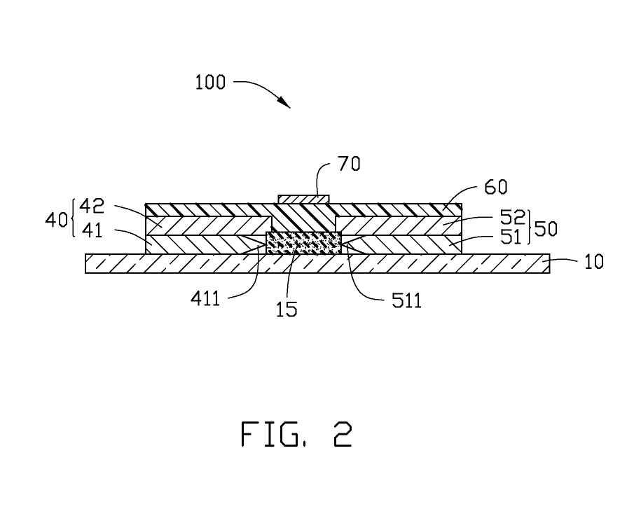

Referring to FIGS. 1 and 2, a transistor 100 provided in an exemplary embodiment is shown. The transistor 100 encompasses a substrate 10, a nanowire-layer 15, a source electrode 40, a drain electrode 50, an insulating layer 60, and a gate electrode 70.

The source electrode 40 and the drain electrode 50 are separately formed on the substrate 10. In detail, the source electrode 40 includes a first electrically conductive layer 41 proximate to the substrate 10, and a second electrically conductive layer 42 laminated on the first electrically conductive layer 42. The drain electrode 50 includes a first electrically conductive layer 51 proximate to the substrate 10 and a second electrically conductive layer 52 laminated on the first electrically conductive layer 51. The first electrically conductive layer 41 of the source electrode 40 has a first pointed portion 411, and the second electrically conductive layer 51 of the drain electrode 50 has a second pointed portion 511 aligned with the first pointed portion 411. Herein pointed portion refer to pointed ends of the electrically conductive layers 41, 51.

The nanowire-layer 15 is formed on the substrate 10 and interposed between the first pointed portion 411 and the second pointed portion 511. The nanowire-layer 15 consists of a plurality of nanowires substantially arranged along a same direction, and functions as an effective channel for transferring electrons between the source electrode 40 and the drain electrode 50.

The insulating layer 60 covers the second electrically conductive layer 42 of the source electrode 40, the second electrically conductive layer 52 of the drain electrode 50, and the nanowire-layer 15. The gate electrode 70 is formed on the insulating layer 60. In this embodiment, the gate electrode 70 is aligned with the nanowire-layer 15.

A method for fabricating the transistor 10 is described below.

A nanowire-dispersed solution is provided. In the present embodiment, the nanowire-dispersed solution can be obtained using the following steps. Firstly, a plurality of nanowires arranged in arrays is formed on a smooth panel. Then, the nanowires are separated from the panel using a solvent. Next, an ultrasonic device is utilized for vibrating the solvent to uniformly disperse the nanowires in the solvent.

A substrate 10 is provided, and a first region 20 and a second region 30 facing the first region 20 are defined on the substrate 10. The substrate 10 is flexible and transparent. In detail, a photoresist layer 11 is formed on the substrate 10. A photo mask having an opening is placed over the photoresist layer 11. The opening has a same shape and size as the first and second electrode regions 20, 30. The photoresist layer 11 is exposed and developed. Thereafter, a portion of the photoresist layer 11 corresponding to the opening is soluble and removed, and the remaining portion of the photoresist layer 11 is solidified. Therefore, the first and second regions 20, 30 are obtained. In the present embodiment, the first and second regions 20, 30 are comb-shaped, and each has a plurality of pointed portions.

The first electrically conductive layer 21 of the source electrode 40 and the first electrically conductive layer 31 of the drain electrode 50 are respectively formed on the first and second regions 20, 30. Thicknesses of the first electrically conductive layers 21, 31 are each approximately equal to the diameter of the nanowires. The remaining photoresist layer is dissolved and removed from the substrate 10.

The nanowire-dispersed solution is coated on the substrate 10 using a slit nozzle and interconnected with each pointed portion couple comprising two opposite pointed portions of the first electrically conductive layers 21, 31. It is understood that the substrate 10 can be immersed in the nanowire-dispersed solution such that the nanowires can be dispersed between the two first electrically conductive layers 21, 31.

Next, an alternating voltage is applied between the two first electrically conductive layers 21, 31, to generate an alternating electric field therebetween. In detail, the two first electrically conductive layers 21, 31 are respectively connected to a negative electrode and a positive electrode of the alternating voltage source.

When the alternating electric field is generated, as described above, the nanowires dispersed in the solvent orient to be parallel to the electric field. Thus, the nanowire-layer 15 is formed.

Particularly, in the present embodiment, the pointed portions of the two first electrically conductive layers 41, 51 ensure proper orientation of the electrical field which in turn helps properly orient the nanowires.

When the nanowire-layer 15 is formed in an aligned state, the alignment thereof is maintained even when the electric field is removed.

Thereafter, the second electrically conductive layer 42 of the source electrode 40 and the second electrically conductive layer 52 of the drain electrode 50 are respectively formed on the first electrically conductive layer 41 of the source electrode 40 and the first electrically conductive layer 51 of the drain electrode 50. As such, the source electrode 40 and the drain electrode 50 are formed.

The substrate 10 is rinsed using dilute water, in order to remove any unwanted nanowire-dispersed solution and avoid a failure caused by foreign matter left on the substrate 10 in a subsequent process.

The insulating layer 60 is formed to cover the source electrode 40, the drain electrode 50, and the nanowire-layer 15.

The gate electrode 70 is formed on the insulating layer 60. In this embodiment, the gate electrode 70 is aligned with the nanowire-layer 15 for improving carrier mobility.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A transistor, comprising:
a substrate;
a source electrode formed on the substrate, the source electrode comprising a plurality of first pointed portions;
a drain electrode formed on the substrate, the drain electrode comprising a plurality of second pointed portions aligned with the respective first pointed portions; and
a nanowire-layer containing a plurality of nanowires, the nanowire-layer formed on the substrate and interconnected between the first pointed portions and the second pointed portions.

2. The transistor of claim 1, further comprising an insulating layer, the insulating layer covering the source electrode, the drain electrode and the nanowire-layer.

3. The transistor of claim 2, wherein each of the source electrode and the drain electrode comprises two laminated electrically conductive layers, the electrically conductive layer of the source electrode proximate to the substrate comprises the first pointed portions, the electrically conductive layer of the drain electrode proximate to the substrate comprises the second pointed portions.

4. The transistor of claim 1, further comprising a gate electrode formed on the opposite side of the insulating layer to the source electrode, the nanowire-layer and the drain electrode.

5. The transistor of claim 4, wherein the gate electrode is aligned with the nanowire-layer.

6. The transistor of claim 1, wherein the source electrode and the drain electrode are comb-shaped electrodes.
